(19) United States
(12) Patent Application Publication
(10) Pub. No.: US 2009/0120676 A1
(43) Pub. Date: May 14, 2009

(54) Process for the production of a conductor track structure

(75) Inventors: Michael Rohm, Furth (DE); Juri Attner, Burgthann (DE)

Correspondence Address: HOFFMANN & BARON, LLP, 6900 JERICHO TURNPIKE, SYOSSET, NY, 11791, US

(73) Assignee: LEONHARD KURZ Stiftung & Co. KG.

(21) Appl. No.: 12/288,718

(22) Filed: Oct. 22, 2008

(30) Foreign Application Priority Data
Oct. 29, 2007 (DE) DE102007051930.5

(51) Int. Cl. H05K 1/18; B32B 37/30; B32B 3/00

(52) U.S. Cl. 174/260; 156/234; 428/195.1

(57) ABSTRACT

The invention concerns a process for the production of a conductor track structure on a flexible plastic film, a conductor track structure produced in accordance therewith, wherein the conductor track structure is connected to the plastic film by means of an adhesive layer hardened by irradiation, and is formed from an electrically conducting thin film layer in pattern form, which is galvanically reinforced with at least one metal layer, as well as an electronic component or an electronic circuit having such a conductor track structure.

### BACKGROUND OF THE INVENTION

The invention concerns a process for the production of a conductor track structure on a flexible plastic film. The invention further concerns conductor track structures which are formed in accordance therewith and electronic components or circuits having such a conductor track structure.

In the mass production of electronic components or circuits, there is generally a need for structuring, that is to say a design configuration in region-wise manner or in pattern form, in respect of the electrically conducting functional layers of the individual components and possibly the connecting lines thereof, for forming circuits. In that respect conductor track structures including electrically conducting connection areas, electrode areas, conductor tracks, antenna elements, coil elements and so forth of electrically conducting material are formed on an electrically insulating substrate and further functional layers like semiconductor layers, electrically insulating layers, bonding layers and so forth are formed in adjoining relationship therewith in order to build up the components and circuits on the substrate. In that respect the electrically insulating substrates used are increasingly flexible, that is to say bendable substrates, such as for example films of plastic material or films including a surface of plastic material, which during the formation of the individual layers of the components and circuits, can be continuously transported in a roll-to-roll procedure. Flexible substrates therefore easily permit mass production of thin flexible and inexpensive components and/or circuits if the individual layers with which the components and circuits are built up are each or in total of such a small layer thickness that the flexibility of the substrate is not adversely affected or is only immaterially adversely affected.

In general various processes for the production of conductor track structures on plastic surfaces are already known.

In a known process a metallic thin film layer is formed on the electrically insulating substrate for example by vapor deposition or sputtering and then galvanically reinforced. Here the term thin film layer is used to denote a layer of a layer thickness of≦2 μm, preferably of a layer thickness of up to 0.5 μm, in particular of a layer thickness of up to 0.1 μm. In that case however it has been found that, when using flexible substrates or films in respect of which at least the surface to be coated is formed from plastic material, the result is frequently insufficient galvanisation of the thin film layer.

At the present time that is attributed to excessively slight adhesion and/or excessively small thickness of the thin film layer, which leads to the thin film layer washing off during the residence time thereof in the galvanic bath. To achieve a satisfactory result hitherto when using flexible substrates of that kind, in respect of which at least the surface to be coated is formed from plastic material, instead of a thin film layer a process is used in which a conductive paste containing metal particles is applied to the substrate in pattern form by printing, hardened and galvanically reinforced. The conductive paste layer formed is a thick film layer, in which respect the term thick film layer is used here to denote a layer of a layer thickness of more than 2 μm, in particular more than 10 μm. By virtue of the greater amount of material used when employing a conductive paste in comparison with using a thin film layer the conductive paste process is thus substantially more cost-intensive.

A further process for the production of conductor track structures on electrically insulating flexible substrates is known from WO 2005/039868 A2. Here a flexible thin plastic film is preferably used as the electrically insulating substrate. An adhesive layer is produced on the plastic film, the adhesive layer being connected to an electrically conducting layer which is provided on a transfer film. As is known transfer films have a self-supporting carrier film and a transfer layer portion which is not self-supporting and which can be detached from the carrier film. The transfer layer portion is formed from at least one layer, here for example a metallic layer for producing a conductor track structure. That known process involves a dry process which substantially avoids contamination of organic semiconductor layers. The organic semiconducting layers of an organic electronic component are extremely sensitive to impurities as when they are present in just low levels of concentration they can already change the electrical properties of the organic semiconductor layer.

### SUMMARY OF THE INVENTION

Now the object of the invention is to provide a further process for the production of conductor track structures, conductor track structures which are formed in accordance therewith and electronic components and circuits which are produced therewith.

That object is attained for the process for the production of a semiconductor track structure on a flexible plastic film, in that an adhesive layer crosslinkable by irradiation is applied to the plastic film or a transfer film and the plastic film and the transfer film are connected together by means of the adhesive layer, wherein the transfer film which has a carrier film and an electrically conducting thin film layer is applied to the plastic film with an orientation of the thin film layer with respect to the adhesive layer crosslinkable by irradiation, wherein the adhesive layer crosslinkable by irradiation is produced in pattern form and/or is irradiated in pattern form in such a way that after irradiation the adhesive layer is present in pattern form in crosslinked hardened form and wherein the carrier film is pulled off the film composite comprising the plastic film, the at least region-wise hardened adhesive layer and the thin film layer, wherein in a first region in pattern form the thin film layer remains on the plastic film and in a second region in pattern form the thin film layer remains on the carrier film and with the carrier film is pulled off the plastic film and wherein the conductor track structure is formed by the thin film layer which in the first region in pattern form has remained on the plastic film being galvanically reinforced with at least one metal layer.

The object is attained for the conductor track structure on a flexible plastic film insofar as it is produced in accordance with the process in accordance with the invention, wherein the conductor track structure is connected to the plastic film by means of an adhesive layer hardened by irradiation and is formed from an electrically conductive thin film layer in pattern form which is galvanically reinforced with at least one metal layer.

The object is further attained for the electronic component or the electronic circuit with a conductor track structure according to the invention, wherein the electronic component is a resistor, a capacitor, an inductor, a field effect transistor (FET), a diode, a light-emitting diode (LED), a solar cell, an OLED display or a film battery or the electronic circuit includes at least one such component.

Surprisingly it has been found that, with a procedure in accordance with the process of the invention, an electrically conducting, in particular metallic thin film layer can certainly be satisfactorily reinforced in a galvanisation procedure with at least one metal layer. Contrary to expectation the thin film layer is not observed as being washed away from the plastic film, as occurs in direct formation of a thin film layer on such a plastic film. At the present time the explanation for this is that, by virtue of the adhesive layer, the adhesion of the thin film layer to the plastic film is markedly improved generally and in particular during the galvanisation procedure.

The process according to the invention makes it possible for the conductor track structures of a component or a circuit to be structured in accurate register relationship and with a high level of resolution. Thus it is possible for example to achieve spacings between a source electrode and a drain electrode of an organic field effect transistor, which are less than 50 μm. By virtue of the at least one galvanically formed metal layer, electrical conductivity of the conductor track structure according to the invention is markedly higher than with a conductor track structure formed by a thin film layer so that the electrical properties of the components or circuits such as for example the lower electrical resistance, the switching speed which is increased by virtue of consequently lower levels of parasitic capacitance or the increased load-carrying capacity with greater current strengths are improved. Further advantages of the process according to the invention are that it is highly inexpensive and suitable for use on a large industrial scale. In addition thermal loading of electrical functional layers of the components or circuits during the production process is avoided.

Advantageous configurations of the process according to the invention, the conductor track structure according to the invention and the electronic components or circuits according to the invention are recited in the appendant claims.

In general, for the process according to the invention, it is possible for the adhesive layer either to be applied directly to the plastic film or however for it to be applied directly to the side of the transfer film on which the thin film layer is disposed. It is only to be noted that, after the plastic film and the transfer film have been brought together, the adhesive layer is between the plastic film and the thin film layer. That also applies to the further embodiments, described hereinafter, of the process according to the invention.

The electronic components involved are in particular organic electronic components which include at least one layer of an organic semiconductor material, in particular an OFET, an OLED or a triac.

Organic semiconductor materials, organic electrically conductive materials and organic electrically insulating materials are in this case formed by organic, metallorganic and/or inorganic substances, in particular polymers, which have the respective electrical properties. By way of example polythiophene can be used as an organic semiconductor material.

Preferably the electronic component or the circuit is mechanically flexible. A component or a circuit is referred to as being flexible if the plastic film including all required electrical functional layers and optionally further layers such as protective layers and so forth is so bendable that it is possible to shape it into a bending radius of a few centimeters, in particular of<10 cm, without involving damage to the plastic film or layers applied thereto of the component or the circuit. In that respect the term damage is used to denote both a visible change such as detachment or lifting off, fracture, discoloration or the like as well as an invisible but measurable change such as a worsening in electrical properties (for example electrical resistance, switching speed and so forth).

The term plastic film is used in accordance with the invention to denote not just a plastic film or a plastic layer comprising a single plastic material but also laminates of the same or different plastic films or plastic layers and laminates including at least one plastic film or plastic layer and further at least one layer portion of paper and/or metal and/or dielectric inorganic or organic material if the surface to which the adhesive layer crosslinked by irradiation is applied is formed from plastic material, which here also includes a lacquer. The plastic film can include for example lacquer layers, electrically insulating layers, semiconducting layers or electrically conducting layers. Thus it is possible that the plastic film already has layers of organic electrically conductive polymers such as polyaniline and polypyrrol, semiconductor layers, for example of polythiophene, and electrically insulating layers, for example of polyvinyl phenol. In that respect it is also possible for those layers to be already present in structured form, that is to say in only region-wise manner, in or on the plastic film. The surface of the plastic film on which the semiconductor track layer is formed is preferably made from an electrically insulating plastic material. That is desirable in particular if the adhesive layer crosslinkable by irradiation is of an electrically conducting nature and/or the adhesive layer is produced in pattern form. When using an electrically insulating adhesive layer which is applied to the plastic film over the full surface area, the surface of the plastic film on which the conductor track structure is formed is also of an electrically conductive nature. A combination of a surface of the plastic film of a semiconducting material with an adhesive layer in pattern form is also possible if the exposed regions of the surface cannot be coated in the galvanic bath.

Preferably the plastic film is of a thickness in the range of between 6 and 200 μm, in particular in the range of between 12 and 150 μm. A plastic film of PET, PC, BOPP, PEN, PVC, ABS or polyimide has proven its worth. It has also proven desirable if the plastic film was thermally stabilised, that is to say subjected to heat treatment prior to its use.

For crosslinking and hardening of the adhesive layer crosslinkable by irradiation, preferably ultraviolet radiation or infrared radiation is used. In that way irradiated regions of the adhesive layer can be crosslinked and hardened particularly quickly and without complication. Radiation devices for producing such kinds of radiation are sufficiently tried-and-tested and are commercially available in many different forms.

The adhesive layer which is hardened by irradiation is in particular of a thickness of≦50 μm, in particular≦2 μm. Preferably the layer thickness is in the range of between 0.5 and 2 μm. An adhesive layer of such a small layer thickness can be optimally integrated into the structure of electronic components or circuits made up from layers. In addition such a thin adhesive layer is usually flexible so that the bendability of the plastic film on which the components or circuits are formed is not adversely affected or only immaterially affected.

It is preferred for the process if the adhesive layer crosslinkable by irradiation is produced in pattern form by means of a printing process, the adhesive layer in pattern form is hardened by irradiation and the carrier film is pulled off the film composite including the plastic film, the hardened adhesive layer in pattern form and the thin film layer, wherein in the first region in pattern form in which the hardened adhesive layer is present the thin film layer remains on the plastic film and in the second region in pattern form in which there is no adhesive layer the thin film layer remains on the carrier film and is pulled with the carrier film off the plastic film. Such a procedure makes it possible to produce conductor track structures in pattern form with a very high level of resolution and excellent electrical conductivity, on the plastic film.

If there is a sufficiently great period of time between the moment of irradiating the adhesive layer in pattern form and the onset of crosslinking and hardening of the adhesive layer, it is however here also possible to join the transfer film together with the plastic film immediately after irradiation of the adhesive layer in pattern form.

It is advantageous to use inexpensive printing procedures which can be employed on a large industrial scale such as intaglio printing, offset printing, flexoprinting or screen printing for forming the adhesive layer in pattern form on the plastic film.

It has further proven desirable if the adhesive layer crosslinkable by irradiation is applied over the full surface area to the plastic film or the transfer film and irradiated in pattern form after glueing of the transfer film to the plastic film whereby the adhesive layer hardens in the first region in pattern form, and the carrier film is pulled off the film composite including the plastic film, the adhesive layer which is present in region-wise hardened form and the thin film layer so that in the first region in pattern form in which the hardened adhesive layer is present the thin film layer remains on the plastic film and in the second region in which the adhesive layer crosslinkable by irradiation is still present the thin film layer is pulled with the carrier film off the plastic film. Such a procedure makes it possible to produce conductor track structures in pattern form with a very high level of resolution and excellent electrical conductivity, on the plastic film. In addition there are cost advantages here as for example there is no need to use high-quality intaglio printing raster rollers, as is necessary for the above-described operation of applying an adhesive layer by printing in pattern form.

If there is a sufficiently great period of time between the moment of irradiating the adhesive layer in pattern form and the onset of crosslinking and hardening of the regions irradiated in pattern form of the adhesive layer, it is however here also possible to join the transfer film together with the plastic film immediately after irradiation of the adhesive layer in pattern form.

It has proven to be advantageous if the thin film layer is semi-transparent, if the carrier film is transmissive in respect of the irradiating radiation and the adhesive layer is irradiated on the side of the transfer film through the transfer film. It has however equally proven worthwhile if the plastic film is transmissive in respect of the irradiating radiation and the adhesive layer is irradiated on the side of the plastic film through the plastic film. It will be appreciated in that respect that both cases must involve at least transmissiveness for the kind of radiation which is used for crosslinking the adhesive layer. Transparency which is perceptible to the human eye is possibly but not necessarily present.

It is particularly advantageous with this embodiment if the adhesive layer crosslinkable by irradiation has a lower adhesion force in relation to the thin film layer than the adhesion force between the thin film layer and the remaining layers of the transfer film such as the carrier film or a release layer which is optionally disposed between the thin film layer and the carrier film. That makes it possible for the carrier film inclusive of the regions of the thin film layer, that are associated with the second region in pattern form, to be pulled off the plastic film without any problem.

A further preferred embodiment provides that the adhesive layer crosslinkable by irradiation is applied over the full surface area to the plastic film or the transfer film, prior to the transfer film being glued to the plastic film the adhesive layer is irradiated in pattern form so that the adhesive layer hardens in pattern form, the transfer film and the plastic film are glued together by means of the adhesive layer which is present in region-wise hardened form, the adhesive layer is now irradiated afresh and hardened in further or all regions, the carrier film is pulled off the film composite including the plastic film, the at least region-wise hardened adhesive layer and the thin film layer so that in the first region in which the adhesive layer was hardened only after joining of the transfer film and the plastic film the thin film layer remains on the plastic film and in the second region in which the adhesive layer was already hardened before the transfer film was brought together with the plastic film and optionally in regions which are still present with the adhesive layer crosslinkable by irradiation the thin film layer is pulled with the carrier film off the plastic film.

The use of the process according to the invention in the context of a roll-to-roll procedure on a large industrial scale is made possible by the use of a drum exposure apparatus or a mask exposure apparatus having a circulating mask belt for irradiation of the adhesive layer in pattern form, in particular with ultraviolet radiation.

It has further proven to be advantageous for the thin film layer to be compressed when it is brought together with the plastic film so that the electrical conductivity thereof is increased by the pressing effect.

The use of a suitable transfer film which permits fast precise detachment of the thin film layer from the carrier film is of particular significance for the process according to the invention. In that respect it has proven to be particularly desirable to provide between the carrier film and the thin film layer of the transfer film, a release layer, for example of wax, silicone or PTFE, which permits defined adjustment of the release characteristics substantially independently of the carrier film used.

It is preferable if the thin film layer is formed by sputtering or vapor deposition or by deposit from a fluid such as a paste, dispersion or solution, on the carrier film or the release layer which is possibly present. The thin film layer is formed on the carrier film or release layer preferably in a layer thickness of≦2 μm, in particular in the region of≦50 nm or in the region of≦10 nm.

The electrically conducting thin film layer is/has been formed in particular from metal or a metal alloy, in particular silver, gold, copper, aluminum or tin or the electrically conducting thin film layer is/has been formed from an organic material, in particular from PEDOT.

In that respect the thin film layer can be formed from an individual layer or from at least two individual layers formed from different materials.

The at least one metal layer galvanically deposited on the thin film layer is/has been preferably formed from copper, chromium, gold, silver, nickel, zinc.

The conductor track structure formed by the thin film layer and the at least one metal layer together is preferably produced in a layer thickness in the range of between 1 and 50 μm. Such conductor track structures have a high level of electrical conductivity and ensure trouble-free operation of components or circuits constructed therefrom.

It has proven desirable if at least two metal layers of different materials are galvanically produced on the thin film layer which is in pattern form. In that case a first deposited metal layer can be formed from a less noble metal, such as for example copper, and a second deposited metal layer can be formed from a more noble metal, for example gold. The gold layer reliably covers over the first metal layer and the thin film layer on the side thereof that is remote from the plastic film and protects the conductor track structure from oxidative influences such as oxygen from the air, air humidity and so forth.

In that respect it has proven desirable if the at least one metal layer is formed by means of electrolytic galvanisation in which electric current flows in the galvanic bath or chemical galvanisation which is effected by a current-less procedure.

In that case the thin film layer is contacted with a current source by contact electrodes which are preferably in bar form and which are guided in a circular movement so that the thin film layer forms an electrode of the flow of current in the galvanic bath and the coating metal is deposited on the thin film layer.

A suitable bath for galvanically depositing for example copper is of the following composition (in parts by weight):

| | | |
|---|---|---|
| 1000 | parts | distilled H₂O |
| 50 | parts | CuSO₄ |
| 10 | parts | H₂SO₄ (98%) |
| 5 | parts | L-ascorbic acid |

For a copper layer or for example 12 μm in thickness to be galvanically deposited from such a bath, the following parameters are preferably adopted:

| | |
|---|---|
| Deposit voltage | 12 V |
| Current density | about 12 A/dm² |
| Deposit time | about 1.5-2 min |
| Bath temperature | 50° C. |

The thickness of the metal layer becomes correspondingly greater, the higher the current density, the deposit voltage and/or the deposit time.

### BRIEF DESCRIPTION OF THE DRAWINGS

The invention is described by way of example hereinafter by means of a number of embodiments with reference to accompanying FIGS. 1 through 4e of the drawing in which:

FIG. 1 shows a functional view of a process implementation in accordance with a first embodiment,

FIG. 2 shows a functional view of a process implementation in accordance with a further embodiment,

FIGS. 3a through 3d show views in cross-section through film composites in accordance with the process implementation of FIG. 1, and

FIGS. 4a through 4e show views in cross-section of the production of an electronic component.

### DETAILED DESCRIPTION OF THE PREFERRED EMBODIMENTS

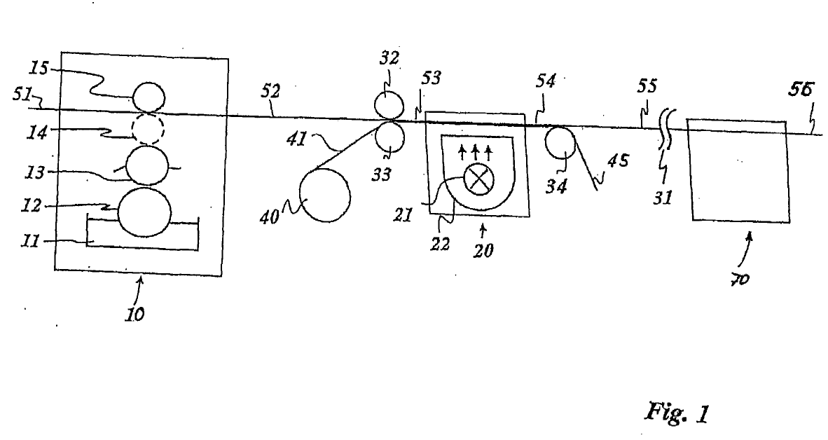

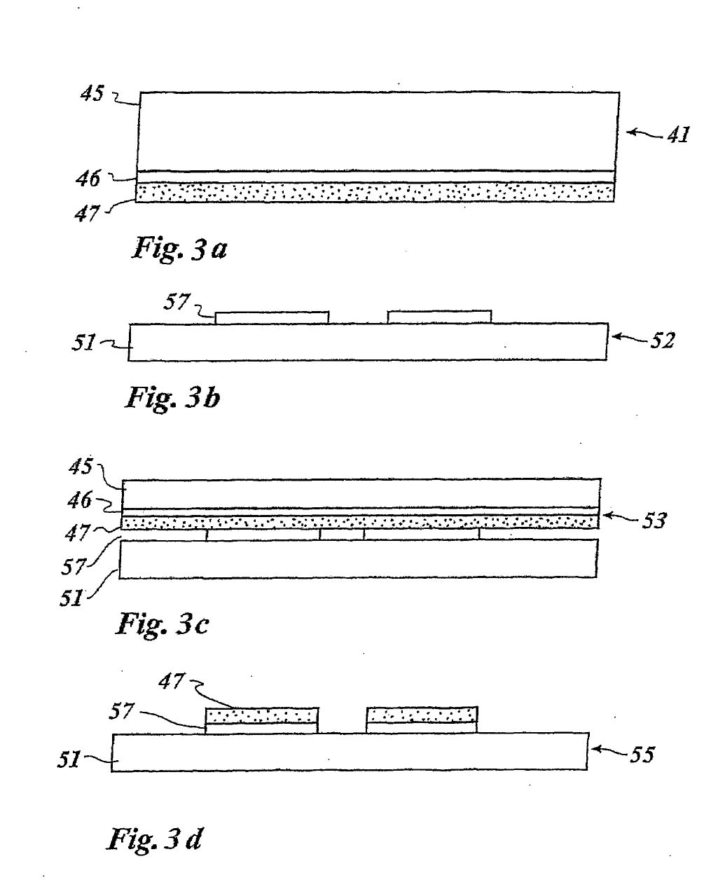

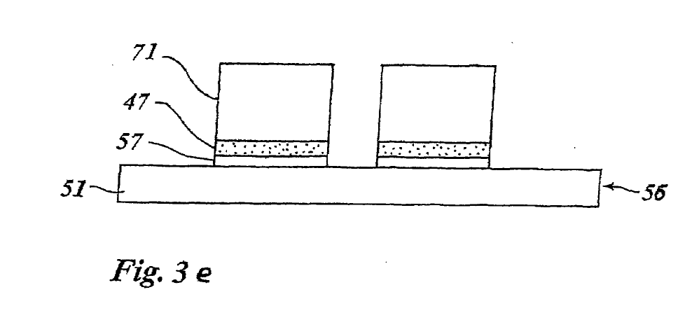

FIG. 1 diagrammatically shows a portion of a roll-to-roll production process in which at least one electrical component is produced on a plastic film 51. FIG. 1 shows a printing station 10, an exposure station 20, three rollers 32, 33 and 34 and a galvanisation station 70. A plastic film 51 of PET of a thickness in the range of between 10 and 150 μm is fed to the printing station 10 and provided with an adhesive layer 57 which is in pattern form and which is crosslinkable by irradiation (see FIG. 3b). That gives the plastic film 52 which is shown in cross-section in FIG. 3b and which has adhesive applied by printing thereto in region-wise manner.

The plastic film 52 which has adhesive applied by printing thereto by the printing station 10 is fed to the pair of rollers 32 and 33 which bring together the plastic film 52 with the adhesive printed thereon and a transfer film 41 unrolled from a roll 40. The transfer film 41 comprises a carrier film 45, an optional release layer 46 and an electrically conducting thin film layer 47 which is detachable from the carrier film 45 (see the cross-section of the transfer film 41 in FIG. 3a), wherein the thin film layer 47 faces towards the adhesive layer 57 when the transfer film 41 and the plastic film 52 with adhesive printed thereon are brought together (for this arrangement see FIGS. 3a and 3b). That gives a first film composite 53 (see the cross-section of the film composite 53 in FIG. 3c) comprising the transfer film 41 and the plastic film 52 with adhesive applied by printing thereto. The first film composite 31 is then fed to the exposure station 20 and the adhesive layer 57 in pattern form is exposed. That entails permanent fixing of regions of the thin film layer 47, which are in contact with the adhesive layer 57 in pattern form, to the plastic film 51. A second film composite 54 comprising the first film composite 53 with the hardened adhesive layer is fed to the roller 34 where the carrier film 41 inclusive of the regions of the thin film layer 47, which are not fixed with adhesive to the plastic film 51, is pulled off the second film composite 54, as transfer film waste 42. Regions of the thin film layer 47 remain fixed on the adhesive layer 57.

By virtue of hardening of the adhesive layer 57 which is in pattern form, the thin film layer 47 is therefore permanently glued to the plastic film 51 precisely at the locations at which the adhesive layer 57 is provided. When subsequently the carrier film 45 is pulled off the thin film layer 47 adheres to the plastic film 51 in the regions in which the adhesive layer 57 was applied by printing and at those locations is separated from the transfer film 41. At the other locations the adhesion between the thin film layer 47 and the carrier film 45, or optionally the release layer 46, predominates, so that here the thin film layer 47 remains on the carrier film 45. There is now a third film composite 55 (see the cross-section of the film composite 53 in FIG. 3d) which is composed of the plastic film 51, the hardened adhesive layer 57 in pattern form and the thin film layer 47 which is in pattern form and which is shaped in correspondingly coincident relationship with the patterned adhesive layer 57 and which is fixed to the plastic film 51 by means of the hardened adhesive layer 57.

The third film composite 55 is put into storage in the region 31 on a roll and is subsequently fed to the galvanisation station 70 in which galvanic coating of the thin film layer 47 which is in pattern form is effected. Alternatively the third film composite 55 is fed directly, that is to say ‘in-line’, to the galvanisation station 50, in which respect it will be noted that adaptation of the printing and exposure process to the galvanisation process which is usually markedly slower must be effected, for example by using a galvanic bath of correspondingly long dimensions and/or at least one deflection device for the third film composite 55 in the galvanic bath in order to ensure a sufficiently long residence time in the galvanic bath.

FIG. 3e is a cross-sectional view showing the resulting fourth film composite 56 after leaving the galvanisation station 70, with the plastic film 51, the hardened adhesive layer 57 in pattern form, the thin film layer 47 in pattern form and a metal layer 71 galvanically deposited on the thin film layer 47 in a configuration corresponding to the form thereof.

The printing station 10 shown in FIG. 1 has a tub with an adhesive 11 which is crosslinkable by irradiation with UV light. The adhesive 11 is applied to a printing cylinder 14 by means of a plurality of transfer rollers 12 and 13. The printing cylinder now applies the adhesive 11 in region-wise manner to the plastic film 51 which is passing through between the printing cylinder 14 and an impression cylinder 15, the adhesive layer 57 in pattern form then being formed. The printing station 10 is preferably an offset printing station or a flexoprinting station. It is however also possible for the printing station 10 to be an intaglio printing or screen printing station.

Preferably the adhesive 11 is applied to the plastic film 51 by printing, in an application weight of between 1 g/m²-5 g/m². Adhesives 11 which are suitable for use in a process according to the invention and which are crosslinkable by irradiation with UV light are offered for example under the following names:

Foilbond UVH 0002 from AKZO NOBEL INKS, and
UVAFLEX UV Adhesive VL000ZA from Zeller+Gmelin GmbH.

Depending on the respective nature of the adhesive 11 used and the way in which the process is implemented, it is possibly necessary in that respect for the plastic film 52 which has been printed upon with adhesive 11 to pass prior to further treatment through a drying passage in which the adhesive layer 57 formed is dried for example at a temperature in the range of between 100 and 120° C.

The release layer 46 of the transfer film preferably comprises wax, silicone or PTFE. It is also possible to dispense with the release layer 46 if the materials of the carrier film 45 and the thin film layer 47 are so selected that the adhesion forces between them do not impede reliable rapid region-wise detachment of the thin film layer 47 from the carrier film 45. Preferably the release layer 46 is applied to the carrier film 45 in a layer thickness in the range of between 0.01 and 0.2 μm.

The release layer 46 is produced for example in accordance with the following composition:

| | | |
|---|---|---|
| Toluene | 99.5 | parts |
| Ester wax (dropping point 90° C.) | 0.5 | part. |

The thin film layer 47 is preferably formed by a thin metallic layer which is applied to the carrier film 45 and optionally the release layer 46, in particular by vapor deposition or sputtering. The thickness of the thin film layer 47 is in particular in the range of between 5 nm and 500 nm in order to ensure high-resolution structurability of the thin film layer 47 by means of the process according to the invention.

Particularly good results can be achieved if the thin film layer 47 has electrically conductive nanoparticles. Such a thin film layer is formed in particular with a layer thickness in the range of between 50 nm and 1 μm and is preferably composed of conductive nanoparticles and binder. The conductive nanoparticles are preferably applied in the form of a dispersion to the release layer 47, which is then dried.

In that case the total layer thickness of the thin film layer 47 and the metal layer 71 together is determined substantially by the electrical properties required in the context of the electronic component, for example the required specific resistance.

The application pressure with which the transfer film 41 is applied by means of the rollers 32, 33 to the plastic film 52 coated with adhesive is to be so selected that the extent of the patterned adhesive layer 47 on the plastic film 51, in terms of the area thereof, is not influenced thereby or is not substantially influenced thereby.

The exposure station 20 shown in FIG. 1 has a UV lamp 21 and a reflector 22 focusing the UV radiation emitted by the UV lamp 21 on to the first film composite 53. In that respect the power of the UV lamp 21 is so selected that, when passing through the exposure station 20, the adhesive layer 57 is irradiated with a sufficiently high amount of energy as to ensure reliable hardening of the adhesive layer 57. As shown in FIG. 1 in that case the first film composite 53 is irradiated from the side of the transfer film 41 through the film 41. That is possible if the thin film layer 47 and the carrier film 45 and, if provided, the release layer 46, comprise a material which is transparent for the UV radiation of the UV lamp. If the transfer film 41 is opaque for the UV radiation, it is possible for the first film composite 53 to be subjected to the action of UV radiation from the side of the plastic film 51, in which case then the plastic film 51 is to be designed to be transparent to the UV radiation of the UV lamp. It is also possible for the adhesive layer 57 to be irradiated on both sides if the plastic film 51 and the transfer film 41 are of suitable natures, in order if necessary to still further shorten the exposure time required for hardening of the adhesive 11.

The fourth film composite 56 which leaves the galvanisation station 70 is subsequently fed directly or after intermediate storage on a further roll to at least one further station for completing the component. In at least one further station (not shown in FIG. 1), the electrical functional layers which are further required are produced over the full surface area or in pattern form, in which case for example one or more functional layers are produced in the form of electrically insulating layers, semiconducting layers, bonding layers, protection layers and so forth.

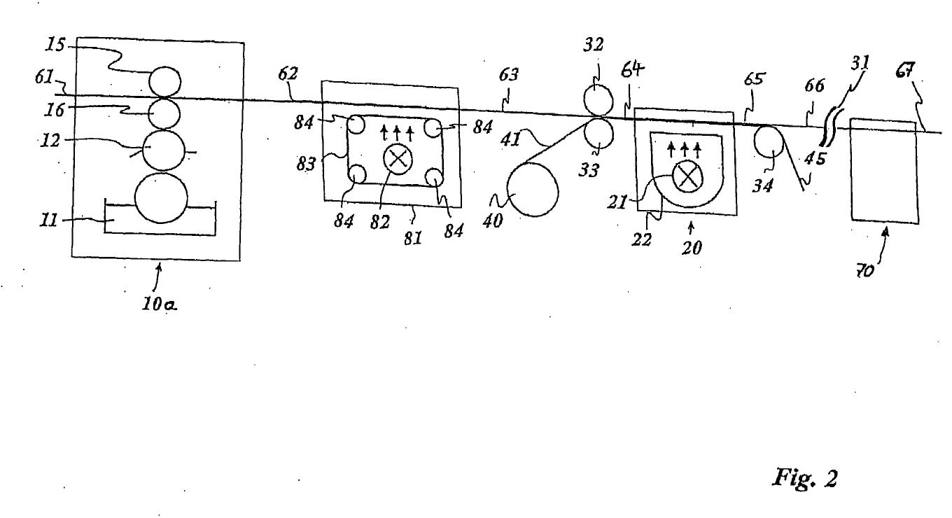

As an alternative to the process of FIG. 1, instead of the exposure station 20 used, it is possible to employ an exposure station 81 (see FIG. 2) in the form of a mask exposure apparatus, in which case the adhesive can be applied to the plastic film 51, alternatively to the transfer film 41, either in pattern form or over the full surface area (see the printing station 10a shown in FIG. 2).

A further embodiment of the invention is now described with reference to FIG. 2. FIG. 2 shows a printing station 10a, a first exposure station 81, a transfer film roll 40, the rollers 32, 33 and 34, a further exposure station 20 and the galvanisation station 70.

The printing station 10a in FIG. 2 is constructed like the printing station 10 in FIG. 1, with the difference that the printing cylinder 14 is replaced by a printing cylinder 16 which applies the adhesive 11 over the full surface area to one side of a supplied plastic film 61. In that case it is also possible for the adhesive layer to be applied to the plastic film 61 not by a printing process but by another coating process, for example painting on, pouring or spraying. Furthermore it is also possible here for the adhesive layer also to be applied to the plastic film 61 in pattern form (as shown in FIG. 1) so that the process described here is combined with the process of FIG. 1.

The plastic film 61 and the adhesive layer applied thereto are like the plastic film 51 and the adhesive layer 57 of FIG. 3b, with the difference that here the adhesive layer 57 is preferably applied over the full surface area to the plastic film 61. Preferably a prepolymeric UV-crosslinkable adhesive is used in this case. The plastic film 62 with the adhesive 11 printed thereon is fed to the first exposure station 81.

The exposure station 81 is a mask exposure apparatus which permits exposure from roll-to-roll by means of a mask belt synchronised with the speed of travel of the plastic film 62 to which adhesive was applied by printing. The mask exposure apparatus thus has a plurality of deflection rollers 84, a mask belt 83 and a UV lamp 82. The mask belt 83 has UV-transparent and opaque or reflecting regions. The mask belt 83 thus forms an endless mask which covers over the adhesive-printed plastic film 62 in relation to the UV lamp 82 and permits continuous irradiation, in pattern form, of the adhesive layer with UV light. As already indicated above the speed of the mask belt 83 is synchronised with the speed of the adhesive-printed plastic film 62, while additional optical markings on the plastic film 62 which is coated with adhesive permit exposure in accurate register relationship, that is to say in the correct position. In this case the power of the UV lamp 82 is so selected that an amount of UV energy sufficient to harden the adhesive layer is supplied by the mask exposure apparatus, when the plastic film 62 with the adhesive printed thereon passes through the station. Preferably the UV light collimated by the mask exposure apparatus is emitted.

Instead of a mask exposure apparatus operating with a mask belt it is also possible to use a drum exposure apparatus having a mask in the form of a drum.

Irradiation of the adhesive layer with UV light in pattern form provides that the adhesive layer is hardened in pattern form so that a composite 63 with patterned, hardened and non-hardened regions of the adhesive layer is fed to the pair of rollers 32, 33. The transfer film 41 is now brought together with the composite 63 by the pair of rollers 32, 33, orientation of the transfer film 41 being effected as already described hereinbefore with reference to FIGS. 1, 3a and 3b. The transfer film 41 is like the transfer film 41 of FIG. 3a. Downstream of the pair of rollers 32, 33, there is a first film composite 64 comprising the plastic film 61, the adhesive layer hardened in pattern form, and the transfer film 41. The first film composite 64 is now fed to a further exposure station 20 which is designed as in FIG. 1. Hardening now also takes place in the regions in which the adhesive layer had not yet been hardened. Downstream of the exposure station 20 there is a second film composite 65 including the transfer film 41, an adhesive layer which is hardened everywhere, and the plastic film 61.

When the carrier film 45 is pulled off the second film composite 65 the thin film layer 47 adheres to the plastic film 61 in the regions of the adhesive layer which were hardened in the exposure station 20, and is detached from the carrier film 45. In the other regions, the adhesion forces between the carrier film 45 and the thin film layer 47, optionally the release layer 46 and the thin film layer 47, provide that, in those regions, the thin film layer 47 is not detached and remains on the carrier film 45. Accordingly, after the carrier film 45 is pulled off, that results in a fourth film composite 66 with a patterned thin film layer 47 which is joined to the adhesive film 61 by way of a hardened adhesive layer which is preferably present over the entire surface area involved. It would optionally be possible to dispense with the exposure station 20 if the adhesion forces between a non-hardened adhesive layer and the thin film layer are higher than between the thin film layer and the carrier film or the release layer.

Further processing of the third film composite 66 and the fourth film composite 67 is effected, as was already effected in relation to the third and fourth film composites 55, 56 in FIG. 1.

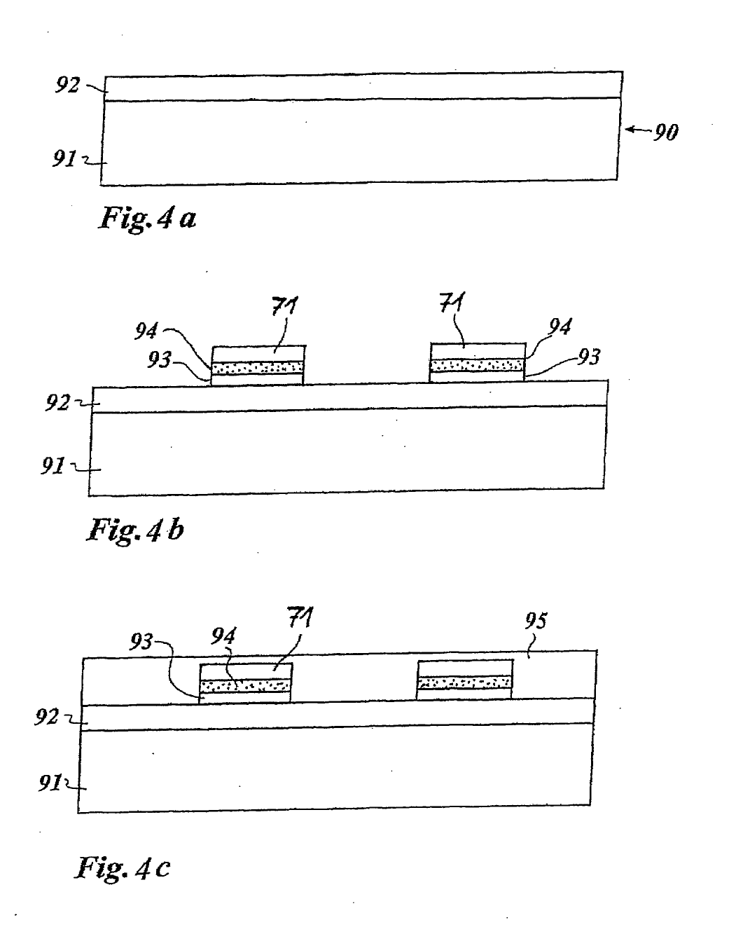

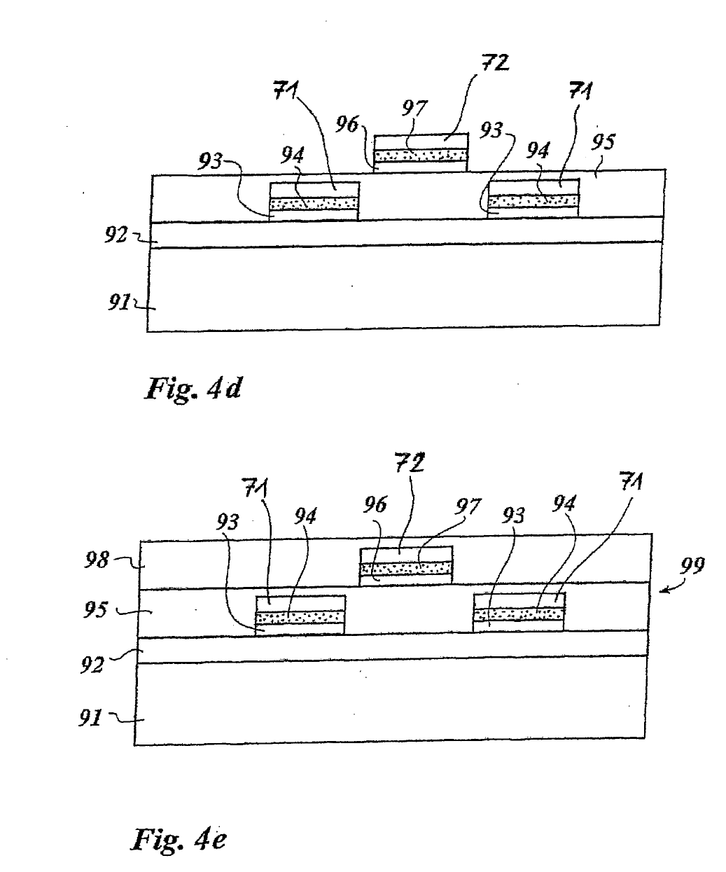

Reference will now be made to FIGS. 4a through 4e to describe by way of example how an electronic component in the form of an organic field effect transistor (OFET) can be produced by means of one of the processes as shown in FIG. 1 or FIG. 2. In that respect FIGS. 4a through 4e show cross-sectional views of the corresponding layers or the component respectively.

FIG. 4a shows a plastic film 90 comprising a carrier film 91 and a lacquer layer 92 applied thereto. The carrier film 91 is a film, preferably a polyester film, of a thickness in the range of between 19 and 38 μm. The lacquer layer 92 is a lacquer layer comprising an electrically insulating material which additionally acts as a protective lacquer layer. The lacquer layer 92 is preferably applied in a thickness in the range of between 0.5 and 5 μm to the carrier film 91 or to a release layer which is possibly disposed between the carrier film 91 and the lacquer layer 92.

Now, as shown in FIG. 4b, an electrically conducting thin film layer 94 is applied to the plastic film 90 in pattern form by means of one of the processes of FIG. 1 or FIG. 2 and a metal layer 71 is galvanically applied to the layer 94. That accordingly affords the film composite which is shown in FIG. 4b and which comprises the carrier film 91, the lacquer layer 92, an adhesive layer 93, the electrically conducting thin film layer 94 and the metal layer 71. In this case the thin film layer 94 and the metal layer 71 each comprise a respective metal or metal alloy and together form the drain and source electrodes of the OFET to be formed. In this case, depending on the respective nature of the process used, it is possible for the adhesive layer 93 to be structured in pattern form in the same manner as the thin film layer 94, as shown in FIG. 4b, or for it to be present in hardened form on the lacquer layer 92 over the full surface area involved.

A semiconducting layer 95 is then applied to the film composite shown in FIG. 4b so that the result is the film composite shown in FIG. 4c, comprising the carrier film 91, the lacquer layer 92, the adhesive layer 93, the thin film layer 94, the metal layer 71 and the semiconducting layer 95. Here, the material used for the semiconducting layer 95 is polythiophene which is applied to the film composite of FIG. 4b in liquid, dissolved form or as a suspension, and solidified. It is also possible for the semiconducting layer 95 to be applied structured in pattern form.

The film composite shown in FIG. 4c now forms a base to which a further electrically conducting thin film layer 97 in pattern form can be applied by means of one of the processes of FIG. 1 or FIG. 2. FIG. 4d shows the film composite resulting therefrom, comprising the carrier film 91, the lacquer layer 92, the adhesive layer 93, the thin film layer 94, the metal layer 71, the semiconducting layer 95, a further adhesive layer 96 and the further thin film layer 97. A further metal layer 72 is galvanically applied to the further thin film layer 97, the metal layer 72 together with the thin film layer 97 forming the gate electrode of the OFET. The adhesive layer 96 is formed from electrically insulating material and is shaped structured in pattern form. The semiconducting layer 95 here forms a further plastic film on which the process is repeated. When using the processes of FIG. 1 or FIG. 2 however it is also possible for the adhesive layer 96 to be applied to the semiconducting layer 95 over the entire surface area involved and for the adhesive layer 96 to form a further plastic film, on which the process is repeated.

If galvanic deposit of the further metal layer 72 adversely affects the semiconducting layer 95 or has a negative effect on the electrical properties of the semiconducting layer 95 the gate electrode can alternatively also be formed directly by sputtering or by vapor deposition by way of a mask, by printing an electrically conductive paste and so forth in pattern form on the semiconductor layer 95.

In a further process step, a further lacquer layer 98 comprising an electrically insulating material is now applied to the film composite shown in FIG. 4d, the further lacquer layer subsequently also performing the function of a protective layer for the semiconducting layer 95. As shown in FIG. 4e that therefore affords an OFET 99 which on the carrier film 91 and the lacquer layer 92 includes the adhesive layer 93, the source and drain electrodes comprising the thin film layer 94 and the metal layer 71, the semiconducting layer 95, the adhesive layer 96 comprising an electrically insulating material, the gate electrode comprising the further thin film layer 97 and the further metal layer 72, as well as the lacquer layer 98.

The formation of further electronic components or circuits (not shown here) is possible quickly and in an uncomplicated fashion by means of the process or processes according to the invention.

1. A process for the production of a semiconductor track structure on a flexible plastic film,
wherein an adhesive layer crosslinkable by irradiation is applied to the plastic film or a transfer film and the plastic film and the transfer film are connected together by means of the adhesive layer, and wherein the transfer film which has a carrier film and an electrically conducting thin film layer is brought together with the plastic film with an orientation of the thin film layer with respect to the adhesive layer crosslinkable by irradiation, wherein the adhesive layer crosslinkable by irradiation is produced in pattern form and/or is irradiated in pattern form in such a way that after irradiation the adhesive layer is present in pattern form in crosslinked hardened form and wherein the carrier film is pulled off the film composite comprising the plastic film the at least region-wise hardened adhesive layer and the thin film layer, wherein in a first region in pattern form the thin film layer remains on the plastic film and in a second region in pattern form the thin film layer remains on the carrier film and with the carrier film is pulled off the plastic film, and wherein the conductor track structure is formed by the thin film layer which in the first region in pattern form has remained on the plastic film being galvanically reinforced with at least one metal layer.

2. A process as set forth in claim 1, wherein the adhesive layer crosslinkable by irradiation is produced in pattern form by means of a printing process, the adhesive layer in pattern form is hardened by irradiation and the carrier film is pulled off the film composite including the plastic film, the hardened adhesive layer in pattern form and the thin film layer, wherein in the first region in pattern form in which the hardened adhesive layer is present the thin film layer remains on the plastic film and in the second region in pattern form in which there is no adhesive layer the thin film layer remains on the carrier film and is pulled with the carrier film off the plastic film.

3. A process as set forth in claim 1, wherein the adhesive layer is printed by means of intaglio printing, offset printing, flexoprinting or screen printing.

4. A process as set forth in claim 1, wherein the adhesive layer crosslinkable by irradiation is applied over the full surface area to the plastic film or the transfer film and irradiated in pattern form after glueing of the transfer film to the plastic film whereby the adhesive layer hardens in the first region in pattern form, and the carrier film is pulled off the film composite including the plastic film, the adhesive layer which is present in region-wise hardened form and the thin film layer so that in the first region in pattern form in which the hardened adhesive layer is present the thin film layer remains on the plastic film and in the second region in which the adhesive layer crosslinkable by irradiation is still present the thin film layer is pulled with the carrier film off the plastic film.

5. A process as set forth in claim 1, wherein the thin film layer is semi-transparent, the carrier film is transmissive for the irradiating radiation and the adhesive layer is irradiated on the side of the transfer film through the transfer film.

6. A process as set forth in claim 1, wherein the plastic film is transmissive for the irradiating radiation and the adhesive layer is irradiated on the side of the plastic film through the plastic film.

7. A process as set forth in claim 4, wherein the adhesive layer crosslinkable by irradiation has a lower adhesion force in relation to the thin film layer than the adhesion force between the thin film layer and the carrier film.

8. A process as set forth in claim 1, wherein the adhesive layer crosslinkable by irradiation is applied over the full surface area to the plastic film or the transfer film, prior to the transfer film being glued to the plastic film, the adhesive layer is irradiated in pattern form so that the adhesive layer hardens in pattern form, the transfer film and the plastic film are glued together by means of the adhesive layer which is present in region-wise hardened form, the adhesive layer is now irradiated afresh and hardened in further or all regions, the carrier film is pulled off the film composite including the plastic film, the at least region-wise hardened adhesive layer and the thin film layer so that in the first region in which the adhesive layer was hardened only after joining of the transfer film and the plastic film the thin film layer remains on the plastic film and in the second region in which the adhesive layer was already hardened before the transfer film was brought together with the plastic film or is now still in non-hardened form the thin film layer is pulled with the carrier film off the plastic film.

9. A process as set forth in claim 1, wherein a mask exposure apparatus is used for the irradiation in pattern form.

10. A process as set forth in claim 1, wherein the thin film layer is compressed on being brought together with the plastic film, thereby increasing electrical conductivity of the thin film layer.

11. A process as set forth in claim 1, wherein the thin film layer is formed by sputtering or vapor deposition or deposit out of a liquid on the carrier film.

12. A process as set forth in claim 1, wherein the thin film layer is formed on the carrier film with a layer thickness of≦2 μm.

13. A process as set forth in claim 1, wherein the conductor track structure is produced with a layer thickness in the range of between 1 and 50 μm.

14. A process as set forth in claim 1, wherein at least two metal layers of different materials are galvanically produced on the thin film layer.

15. A process as set forth in claim 1, wherein the at least one metal layer is formed by means of electrolytic galvanisation.

16. A process as set forth in claim 1, wherein the at least one metal layer is formed by means of chemical galvanisation.

17. A conductor track structure comprising a flexible plastic film which can be produced as set forth in claim 1, wherein the conductor track structure is joined to the plastic film by means of an adhesive layer hardened by irradiation, and is formed from an electrically conducting thin film layer in pattern form, which is galvanically reinforced with at least one metal layer.

18. A conductor track structure as set forth in claim 17, wherein the plastic film is of a thickness in the range of between 12 and 150 μm.

19. A conductor track structure as set forth in claim 17, wherein the plastic film is formed from PET, PC, BOPP, PEN, PVC, ABS or polyimide.

20. A conductor track structure as set forth in claim 17, wherein the thin film layer is formed from metal or a metal alloy, or the thin film layer is formed from an organic material.

21. A conductor track structure as set forth in claim 17, wherein the at least one metal layer is formed from copper, chromium, gold, silver, nickel or zinc.

22. A conductor track structure as set forth in claim 17, wherein the thin film layer and the at least one metal layer together are of a layer thickness in the range of between 1 and 50 μm.

23. A conductor track structure as set forth in claim 17, wherein the hardened adhesive layer is of a layer thickness of≦50 μm.

24. An electronic component or electronic circuit having a conductor track structure as set forth in claim 17, wherein the electronic component is a resistor, a capacitor, an inductor, a field effect transistor (FET), a diode, a light-emitting diode (LED), a solar cell, an OLED display or a film battery or that the electronic circuit includes at least one such component.

25. An electronic component or electronic circuit as set forth in claim 24, wherein the electronic component is an organic component.

26. An electronic component or electronic circuit as set forth in claim 24, wherein the component or the circuit is adapted to be mechanically flexible.
